(19) United States
(12) Patent Application Publication
(10) Pub. No.: US 2006/0062916 A1
(43) Pub. Date: Mar. 23, 2006

(54) Atomic layer deposition apparatus and method

(75) Inventor: Seok-jun Won, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/148,823

(22) Filed: Jun. 9, 2005

(30) Foreign Application Priority Data
Sep. 22, 2004 (KR) 10-2004-0075963

(51) Int. Cl. C23C 16/00

(52) U.S. Cl. 427/248.1; 118/715

(57) ABSTRACT

In an atomic layer deposition (ALD) apparatus and method, an ALD apparatus includes a reactor where reactions occur; a main purge line connected to the reactor and including a first main purge line, a second main purge line, and a selection valve installed at a connection portion between the first and second main purge lines; a reactant gas line through which a reactant gas and a reactant purge gas are supplied to the reactor; a source gas line through which a source gas and a source purge gas are supplied to the reactor; an exhaust line through which any non-reacted source gas, reactant gas, and purge gas, which remain in the reactor after reactions, are exhausted; and a vent line branched from the source gas line and connected to the exhaust line.

This application claims the priority of Korean Patent Application No. 10-2004-0075963, filed on Sep. 22, 2004, in the Korean Intellectual Property Office, the disclosure of which is incorporated herein in its entirety by reference.

### BACKGROUND OF THE INVENTION

1. Field of the Invention

The present invention relates to an atomic layer deposition (ALD) apparatus and method, and more particularly, to an ALD apparatus and method, in which a source gas can be efficiently supplied and purged.

2. Description of the Related Art

In an ALD method, a source gas and a reactant gas are supplied to a reactor in a cyclic manner, thereby forming layers. Specifically, each set of process steps, namely, supply of a source gas to a reactor, purge of the source gas from the reactor, supply of a reactant gas to the reactor, and purge of the reactant gas from the reactor, which are performed to form an atomic layer, is referred to as a cycle. The process is repeated for a number of cycles needed to form a desired film thickness. An ALD apparatus includes a reactor and various gas supply lines and exhaust lines to embody the ALD method.

FIG. 1A is a schematic view of a conventional ALD apparatus in a stand-by mode, and FIGS. 1B through 1E are schematic views illustrating respective process steps of an ALD method that are performed using the ALD apparatus illustrated in FIG. 1A. Specifically, FIG. 1B illustrates supply of a source gas, FIG. 1C illustrates supply of a source purge gas, FIG. 1 D illustrates supply of a reactant gas, and FIG. 1E illustrates supply of a reactant purge gas. In the figures, a black circle refers to an open valve, a white circle refers to a closed valve, and a line through which a gas is flowing is illustrated with a darkened, solid line. FIG. 1A illustrates a basic structure of the ALD apparatus, and FIGS. 1B through 1D each illustrate an operating state of the ALD apparatus depending on whether a valve is opened or closed off and whether or not a reactant gas is supplied.

Referring to FIG. 1A, a main purge line 20 having a first valve v1 and a reactant gas line 30 having a second valve v2 are connected to a reactor 10. A source gas line 50 is connected to the main purge line 20 by a third valve v3. The source gas line 50 includes a source purge line 40 having a fourth valve v4 and a source gas supply line 45 having both terminals connected to the source purge line 40. The source gas supply line 45 passes through a source bottle 47 and has a front terminal and a rear terminal at which a fifth valve v5 and a sixth valve v6 are installed, respectively. A variety of gases remaining in the reactor 10 flow through a throttle valve 70 and a pump 80 and are exhausted via an exhaust line 60. A vent line 90 branched from the source gas line 50 has a seventh valve v7 and is connected to the exhaust line 60 between the throttle valve 70 and the pump 80.

When the ALD apparatus is in a stand-by mode as illustrated in FIG. 1A, an operating state of the ALD apparatus is the same as when the source gas is purged as illustrated in FIG. 1C and when the reactant gas is purged as illustrated in FIG. 1E. Specifically, referring to FIGS. 1A, 1C, and 1E, it can be observed that the source gas is purged through two purge lines. That is, the main purge line 20 is used to purge the reactor 10, while the source purge line 40 is connected to the exhaust line 60 without passing through the reactor 10. The reason why the source gas is purged using the two purge lines is that the source gas can be efficiently purged by separately purging the source gas line 50, which has many valves and is difficult to purge, from the reactor 10. As can be seen from figures, the source purge line 40 having many valves remains purged even while the source gas is being purged or the reactant gas is being supplied/purged.

In the ALD apparatus illustrated in FIGS. 1A through 1E, as the flow rate of a purge gas flowing through the main purge line 20 increases, purge efficiency improves. However, even while the reactant gas is being supplied as illustrated in FIG. 1D, the purge gas is continuously supplied. As a result, the partial pressure of the reactant gas is reduced, and wafer throughput is more likely increase with an increase in the overall flow rate. If the flow rate of the source purge gas flowing through the source purge line 40 is increased, purge efficiency is enhanced but the partial pressure of the source gas is decreased during the supply of the source gas. In order to supply the source gas more efficiently, the partial inside diameter of the vent line 90 may be narrowed so that conductance of the line is changed. For example, the inside diameter of the vent line 90 may be reduced from 4 mm to 1 mm. In this case, as the pressure applied to the source gas line 50 increases, the initial pressure applied to the source bottle 47 increases. Thus, a large amount of source gas is supplied in a short time, so that the source gas supplied to the surface of the wafer is rapidly saturated. However, this method of narrowing the inside diameter of the vent line 90 adversely affects the purge efficiency in the source gas line 50.

The ALD apparatus illustrated in FIGS. 1A through 1E has another problem. That is, the ALD apparatus includes a path that is connected to neither the main purge line 20 nor the source purge line 40 and where the source gas accumulates, i.e., a dead volume 95. In particular, when a compound thin layer is deposited, such a dead volume 95 results in generation of particles due to a vapor phase reaction and deteriorates uniformity and other properties of the layer.

### SUMMARY OF THE INVENTION

The present invention provides an atomic layer deposition (ALD) apparatus, in which a source gas can be efficiently supplied and purged.

Also, the present invention provides an ALD method, in which a source gas can be efficiently supplied and purged.

In one aspect of the present invention, there is provided an atomic layer deposition apparatus including: a reactor where reactions occur; a main purge line connected to the reactor; a reactant gas line through which a reactant gas and a reactant purge gas are supplied to the reactor; a source gas line through which a source gas and a source purge gas are supplied to the reactor; an exhaust line through which any non-reacted source gas, reactant gas, and purge gas, which remain in the reactor after reactions, are exhausted; and a vent line branched from the source gas line and connected to the exhaust line. The main purge line includes a first main purge line, a second main purge line, and a selection valve installed at a connection portion between the first and second main purge lines.

In one embodiment, the selection valve is opened during supply of the source gas and during supply of the source purge gas. In another embodiment, the selection valve is closed off during supply of the reactant gas and during supply of the reactant purge gas.

In another embodiment, each of the first and second main purge lines has a first valve, a second valve is installed in the reactant gas line, the source gas line is connected to the main purge line by a third valve, the source gas line includes a source purge line having a fourth valve and a source gas supply line having both terminals connected to the source purge line, the source gas supply line passes through a source bottle and has a front terminal and a rear terminal at which a fifth valve and a sixth valve are installed, respectively, a throttle valve and a pump are connected to the exhaust line, and the vent line branched from the source gas line has a seventh valve and is connected to the exhaust line between the throttle valve and the pump.

In another embodiment, the fourth and seventh valves are closed off and the first, second, third, fifth, and sixth valves and the selection valve are opened during supply of the source gas. In another embodiment, the third, fifth, and sixth valves are closed off and the first, second, fourth, and seventh valves and the selection valve are opened during supply of the source purge gas. In another embodiment, the fifth and sixth valves and the selection valve are closed off and the first through fourth and seventh valves are opened during supply of the reactant gas and during supply of the reactant purge gas.

In another embodiment, the vent line includes a first vent line, a second vent line having a higher conductance than the first vent line, and valves installed in the first and second vent lines, respectively. In another embodiment, the valve installed in the first vent line is closed off and the valve installed in the second vent line is opened during supply of the source purge gas. In another embodiment, the valve installed in the second vent line is closed off and the valve installed in the first vent line is opened during supply of the reactant gas and during supply of the reactant purge gas.

In another embodiment, each of the first and second main purge lines has a first valve, a second valve is installed in the reactant gas line, the source gas line is connected to the main purge line by a third valve, the source gas line includes a source purge line having a fourth valve and a source gas supply line having both terminals connected to the source purge line, the source gas supply line passes through a source bottle and has a front terminal and a rear terminal at which a fifth valve and a sixth valve are installed, respectively, a throttle valve and a pump are connected to the exhaust line, and the vent line branched from the source gas line has a seventh valve and is connected to the exhaust line between the throttle valve and the pump.

In another embodiment, the fourth valve and the valves of the first and second vent lines are closed off and the first, second, third, fifth, and sixth valves and the selection valve are opened during supply of the source gas.

In another embodiment, the third, fifth, and sixth valves and the valve of the first vent line are closed off and the first, second, and fourth valves, the selection valve, and the valve of the second vent line are opened during supply of the source purge gas.

In another embodiment, the fifth and sixth valves, the selection valve, and the valve of the second vent line are closed off and the first through fourth valves and the valve of the first vent line are opened during supply of the reactant gas and during supply of the reactant purge gas.

In another embodiment, the main purge line is connected to the source gas line by a valve.

According to another aspect of the present invention, there is provided an atomic layer deposition apparatus including: a reactor where reactions occur; a main purge line connected to the reactor; a reactant gas line through which a reactant gas and a reactant purge gas are supplied to the reactor; a source gas line through which a source gas and a source purge gas are supplied to the reactor; an exhaust line through which any non-reacted source gas, reactant gas, and purge gas, which remain in the reactor after reactions, are exhausted; and a vent line branched from the source gas line and connected to the exhaust line. The vent line includes a first vent line, a second vent line having a higher conductance than the first vent line, and valves installed in the first and second vent lines, respectively.

According to still another aspect of the present invention, there is provided an atomic layer deposition method including: mounting a wafer in a reactor where reactions occur and supplying a source gas to the reactor. At this time, a main purge line connected to the reactor may include a first main purge line, a second main purge line, and a selection valve installed at a connection portion between the first and second main purge lines. The source gas is supplied to the reactor by opening the selection valve such that both the first and second main purge lines communicate with the reactor. Then, a source purge gas is supplied to the reactor by opening the selection valve such that both the first and second main purge lines communicate with the reactor, and a reactant gas is then supplied to the reactor by closing off the selection valve such that only the second main purge line communicates with the reactor. Then, a reactant purge gas is supplied to the reactor by closing off the selection valve such that only the second main purge line communicates with the reactor.

In one embodiment, a vent line is connected between a source gas line, through which the source gas and the source purge gas are supplied to the reactor, and an exhaust line, through which a non-reacted source gas, reactant gas, and purge gas remaining in the reactor after reactions are exhausted, and wherein the vent line includes a first vent line, a second vent line having a higher conductance than the first vent line, and valves installed in the first and second vent lines, respectively.

In another embodiment, the supplying of the source purge gas comprises closing off the valve of the first vent line and opening of the valve of the second vent line.

In another embodiment, the supplying of the reactant gas and the supplying of the reactant purge gas comprise closing off the valve of the second vent line and opening the valve of the first vent line.

According to yet another aspect of the present invention, there is provided an atomic layer deposition method including: mounting a wafer in a reactor where reactions occur; supplying the source gas to the reactor by closing off the valves of first and second vent lines, wherein the first and second vent lines respectively including a valve constitutes to a vent line branched from the source gas line through which a source gas and a source purge gas are supplied to the reactor and connected to the exhaust line through which a non-reacted source gas, reactant gas, and purge gas, which remain in the reactor after reactions, are exhausted; supplying the source purge gas to the reactor by closing off the valve of the first vent line and opening the valve of the second vent line; supplying a reactant gas to the reactor by closing off the valve of the second vent line and opening the valve of the first vent line; and supplying a reactant purge gas to the reactor by closing off the valve of the second vent line and opening the valve of the first vent line.

In the atomic layer deposition apparatus, the main purge line and/or the vent line each are comprised of a dual line. Thus, a selected line is appropriately changed during the supply of each of a source gas, a source purge gas, a reactant gas, and a reactant purge gas so that the source gas can be efficiently supplied and purged.

### BRIEF DESCRIPTION OF THE DRAWINGS

The above and other features and advantages of the present invention will become more apparent by describing in detail exemplary embodiments thereof with reference to the attached drawings in which:

FIG. 1A is a schematic view of a conventional atomic layer deposition (ALD) apparatus in a stand-by mode;

FIGS. 1B through 1E are schematic views illustrating respective process steps of an ALD method that are performed using the ALD apparatus illustrated in FIG. 1A;

FIG. 2A is a schematic view of an ALD apparatus in a stand-by mode according to an embodiment of the present invention;

FIGS. 2B through 2E are schematic views illustrating respective process steps of an ALD method that are performed using the ALD apparatus illustrated in FIG. 2A;

FIG. 3A is a schematic view of an ALD apparatus in a stand-by mode according to another embodiment-of the present invention;

FIGS. 3B through 3E are schematic views illustrating respective process steps of an ALD method that are performed using the ALD apparatus illustrated in FIG. 3A;

FIG. 4A is a schematic view of an ALD apparatus in a stand-by mode according to yet another embodiment of the present invention; and

FIGS. 4B through 4E are schematic views illustrating respective process steps of an ALD method that are performed using the ALD apparatus illustrated in FIG. 4A.

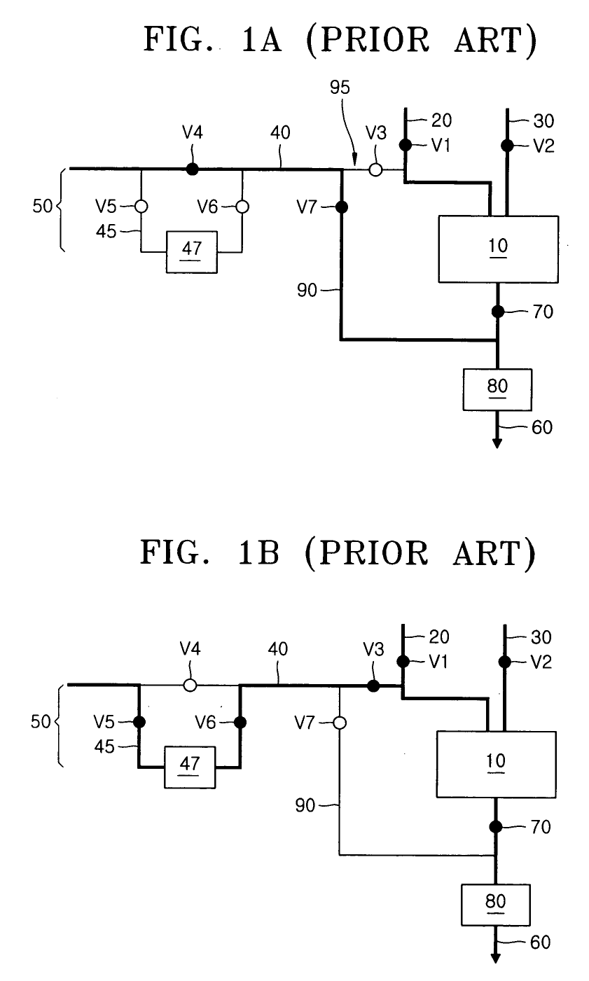

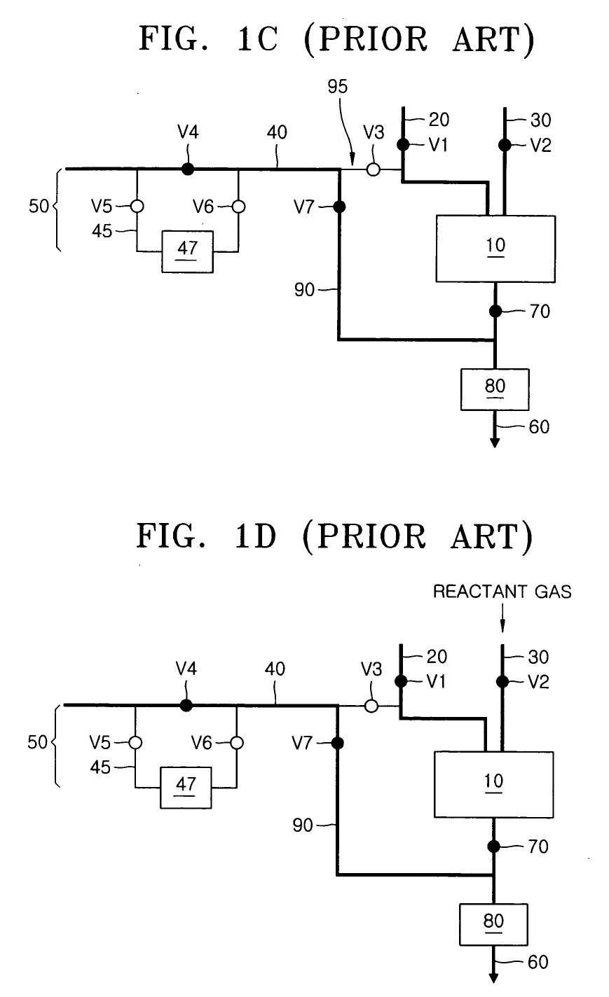

### DETAILED DESCRIPTION OF THE INVENTION

The present invention will now be described more fully with reference to the accompanying drawings, in which exemplary embodiments of the invention are shown. This invention may, however, be embodied in different forms and should not be construed as being limited to the embodiments set forth herein. To facilitate understanding, identical reference numerals have been used, where possible, to designate identical elements that are common to the figures.

### Embodiment 1

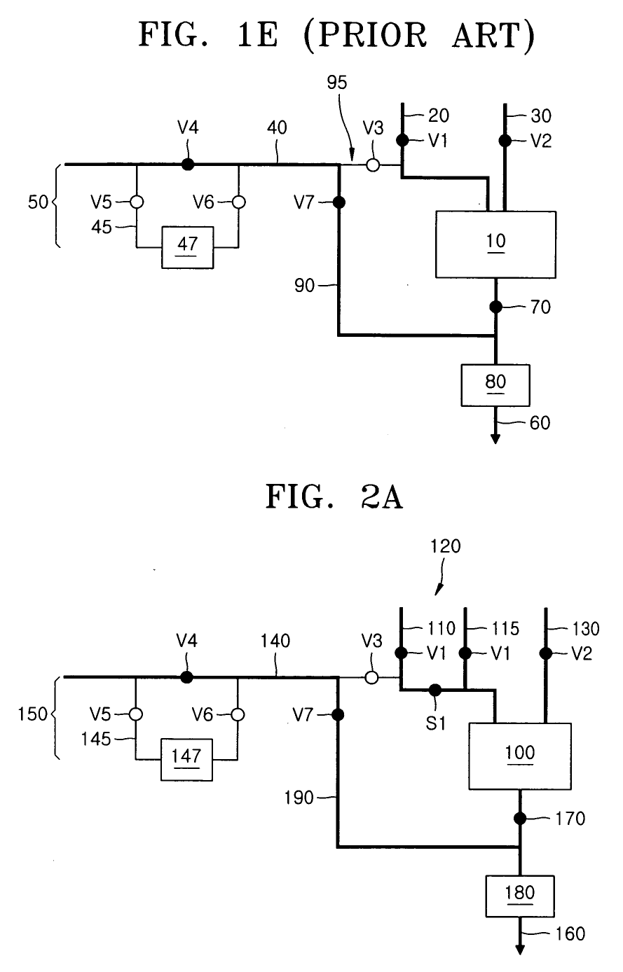

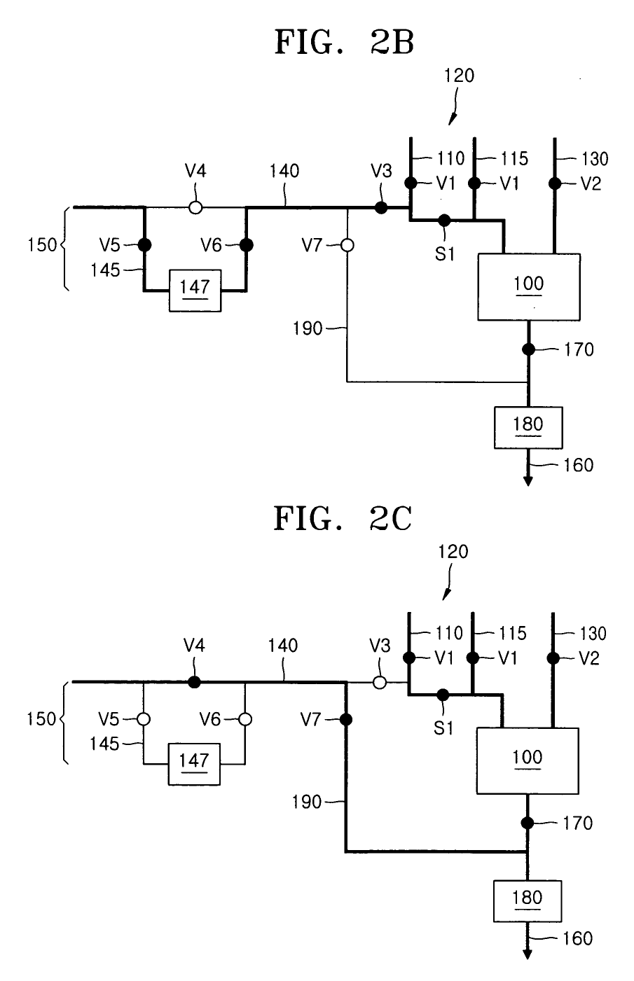

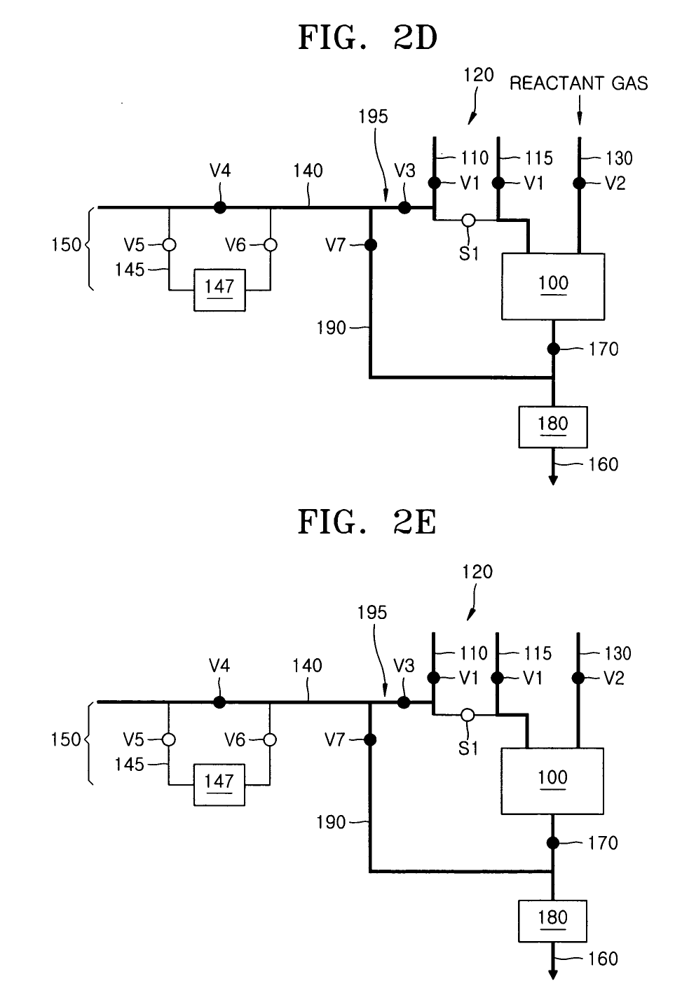

FIG. 2A is a schematic view of an ALD apparatus in a stand-by mode according to an embodiment of the present invention, and FIGS. 2B through 2E are schematic views illustrating respective process steps of an ALD method that are performed using the ALD apparatus illustrated in FIG. 2A. Specifically, FIG. 2B illustrates supply of a source gas, FIG. 2C illustrates supply of a source purge gas, FIG. 2D illustrates supply of a reactant gas, and FIG. 2E illustrates supply of a reactant purge gas. For instance, when an atomic layer is formed of hafnium oxide (HfO₂), which has recently attracted considerable attention as a high-k material, TEMAH is used as a source gas, and O₂ gas is used as a reactant gas. In addition to HfO₂, the ALD apparatus and method of the present invention can form an atomic layer using other various materials, such as tantalum oxide, indium oxide, tin oxide, ruthenium oxide, iridium oxide, titanium oxide, aluminum oxide, zirconium oxide, and silicon oxide. In the figures, a black circle refers to an open valve, a white circle refers to a closed valve, and a line through which a gas is flowing is illustrated with a solid, darkened line. FIG. 2A illustrates a basic structure of the ALD apparatus, and FIGS. 2B through 2D each illustrate an operating state of the ALD apparatus depending on whether a valve is opened or closed off and whether or not a reactant gas is supplied.

Referring to FIG. 2A, a main purge line 120 is connected to a reactor 100 where reactions occur. The main purge line 120 includes a first main purge line 110, a second main purge line 115, and a selection valve s1 installed at a connection portion between the first and second main purge lines 110 and 115. Each of the first and second main purge lines 110 and 115 has a first valve v1 installed at a terminal of the selection valve s1. Also, the reactor 100 is connected to a reactant gas line 130, through which a reactant gas and a reactant purge gas are supplied to the reactor 100 (here, the reactant purge gas (e.g., an inert gas such as N₂ or Ar) is used to purge the reactant gas during the purge of the reactant gas, but functions as a reactant gas carrier during the supply of the reactant gas). A second valve v2 is installed in the reactant gas line 130.

The main purge line 120 is connected to a source gas line 150, through which a source gas and a source purge gas are supplied to the reactor 100, by a third valve v3 (here, the source purge gas (e.g., an inert gas such as N₂ or Ar) is used to purge the source gas during the purge of the source gas, but functions as a source gas carrier during the supply of the source gas). The source gas line 150 includes a source purge gas line 140 having a fourth valve v4 and a source gas supply line 145 having both terminals connected to the source purge line 140. The source gas supply line 145 passes through a source bottle 147 and has a front terminal and a rear terminal at which a fifth valve v5 and a sixth valve v6 are installed, respectively. A non-reacted source gas, reactant gas, and purge gas, which remain in the reactor 100 after reactions, are exhausted via an exhaust line 160 to which a throttle valve 170 and a pump 180 are connected. A vent line 190 branched from the source gas line 150 has a seventh valve v7 and is connected to the exhaust line 160 between the throttle valve 170 and the pump 180.

As can be seen from FIG. 2A, the first embodiment is characterized by the main purge line 120 comprised of a dual purge line, i.e., the first and second main purge lines 110 and 150. In an atmospheric state, the third, fifth, and sixth valves v3, v5, and v6 are closed off. In particular, the selection valve s1 is opened, thereby allowing the entire purge gas flowing from the first and second main purge lines 110 and 115 to flow into the reactor 100. For example, a purge gas of 50 sccm is supplied to each of the first and second main purge lines 110 and 115 so that a purge gas of about 100 sccm flows into the reactor 100.

An example of an ALD method using the ALD apparatus illustrated in FIGS. 2A through 2E is as follows. At the outset, a wafer is mounted in the reactor 100, and the, ALD apparatus is in a stand-by mode as illustrated in FIG. 2A. Then, a process including steps illustrated in FIGS. 2B through 2E is referred to a cycle, and the process is repeated for a number of cycles until a layer having a desired thickness is deposited on the wafer.

FIG. 2B illustrates supply of the source gas using the ALD apparatus illustrated in FIG. 2A. The fourth and seventh valves v4 and v7 are closed off and the remaining valves v1, v2, v3, v5, and v6 are opened, such that the source gas is supplied to the reactor 100. The selection valve s1 is also opened such that the first and second main purge lines 110 and 115 communicate with the reactor 100, thus allowing the entire purge gas supplied to the first and second main purge lines 110 and 115 to flow into the reactor 100. For example, as described above with reference to FIG. 2A, a purge gas of 50 sccm is supplied to each of the first and second main purge lines 110 and 115 such that a purge gas of about 100 sccm flows into the reactor 100. The throttle valve 170 is not completely opened or closed off during the supply of the source gas. In order to maintain a constant pressure, an angle at which the throttle valve 170 is opened is controlled or fixed.

FIG. 2C illustrates supply of the source purge gas using the ALD apparatus illustrated in FIG. 2A and illustrates the same operating state as in FIG. 2A. That is, the selection valve s1 is opened such that the entire purge gas supplied to the first and second man purge lines 110 and 115 flows into the reactor 100.

FIG. 2D illustrates supply of the reactant gas using the ALD apparatus illustrated in FIG. 2A. The reactant gas is supplied through the reactant gas line 130 to the reactor 100, and the fifth and sixth valves v5 and v6 and the selection valve s1 remain closed off. Then, only the second main purge line 115 communicates with the reactor 100 SO that some of the purge gas supplied to the first main purge line 110 flows toward the vent line 190, while the other of the purge gas supplied to the second main purge line 115 flows toward the reactor 100. If a purge gas of 50 sccm is supplied to each of the first and second main purge lines 110 and 115 as exemplarily described above, as the selection valve s1 is closed off, only the purge gas of 50 sccm flowing from the second main purge line 115 is supplied to the reactor 100. Since a conventional ALD apparatus includes only a single main purge line, during supply of a reactant gas, the whole purge gas flows into a reactor through the single main purge line, thus decreasing the partial pressure of the reactant gas. On the other hand, in the present embodiment, by closing off the selection valve s1, only the purge gas supplied to the second main purge line 115 flows into the reactor 100 so that the partial pressure of the reactant gas can increase. The partial pressure of the reactant gas greatly affects the removal of impurities and the step coverage of a thin film and thus, has a notable influence on the electric characteristics of the thin film. Accordingly, increasing the partial pressure of the reactant gas is highly desirable. Also, as the selection valve s1 is closed off, the purge gas supplied to the first main purge line 110 flows toward the vent line 190, so that even a portion 195 corresponding to a dead volume of the conventional ALD apparatus can be purged. Therefore, the present embodiment can efficiently purge the source gas by solving problems caused by the dead volume.

FIG. 2E illustrates supply of the reactant purge gas using the ALD apparatus illustrated in FIG. 2A and illustrates the same operating state as in FIG. 2D, but only the purge gas is supplied to the reactant gas line 130. Similarly, the portion 195 corresponding to the dead volume of the conventional ALD apparatus is purged due to the purge gas flowing through the first main purge line 110.

### Embodiment 2

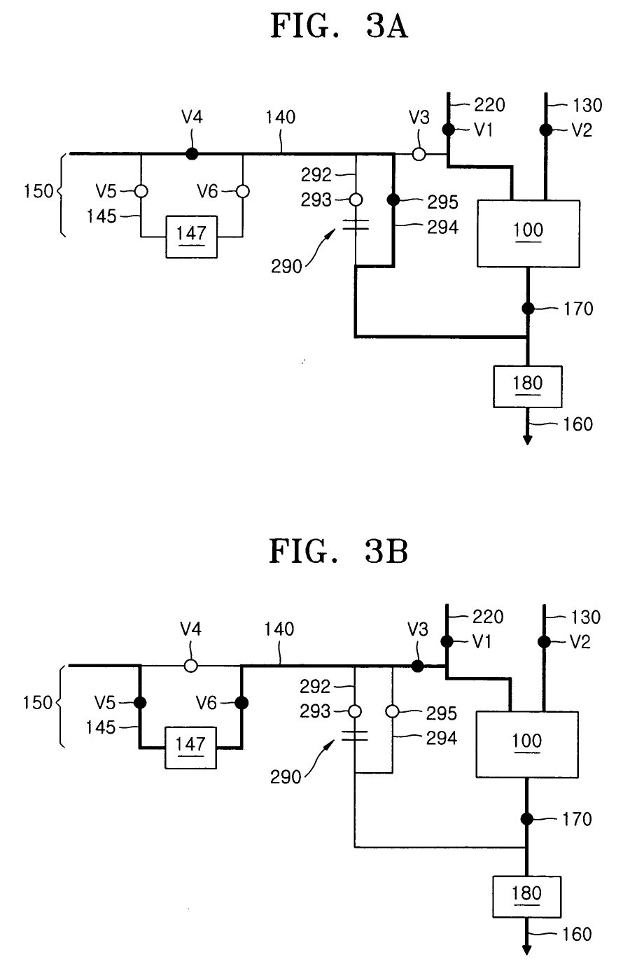

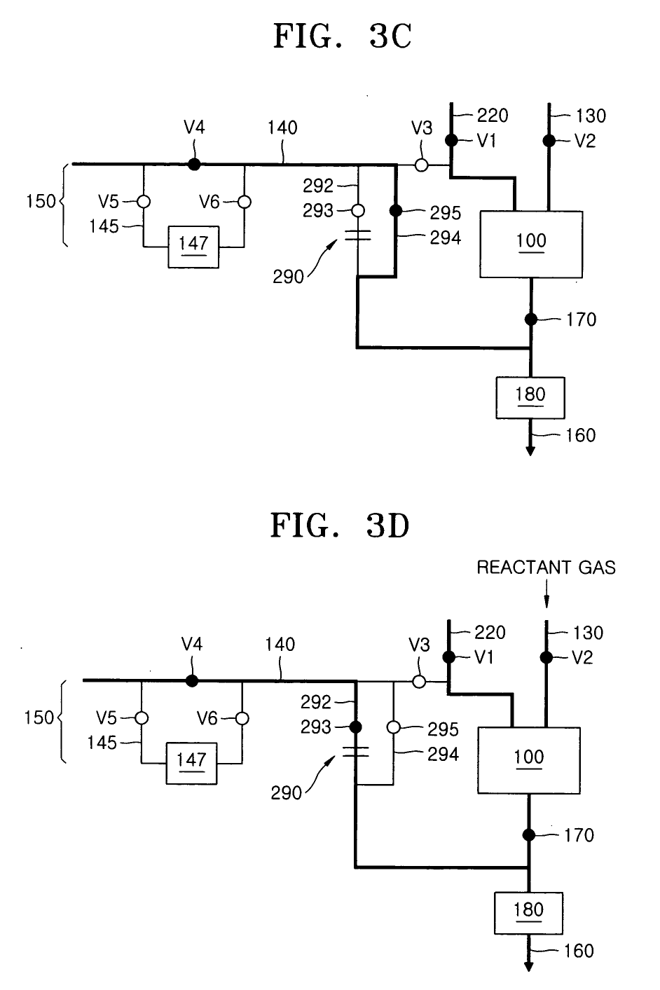

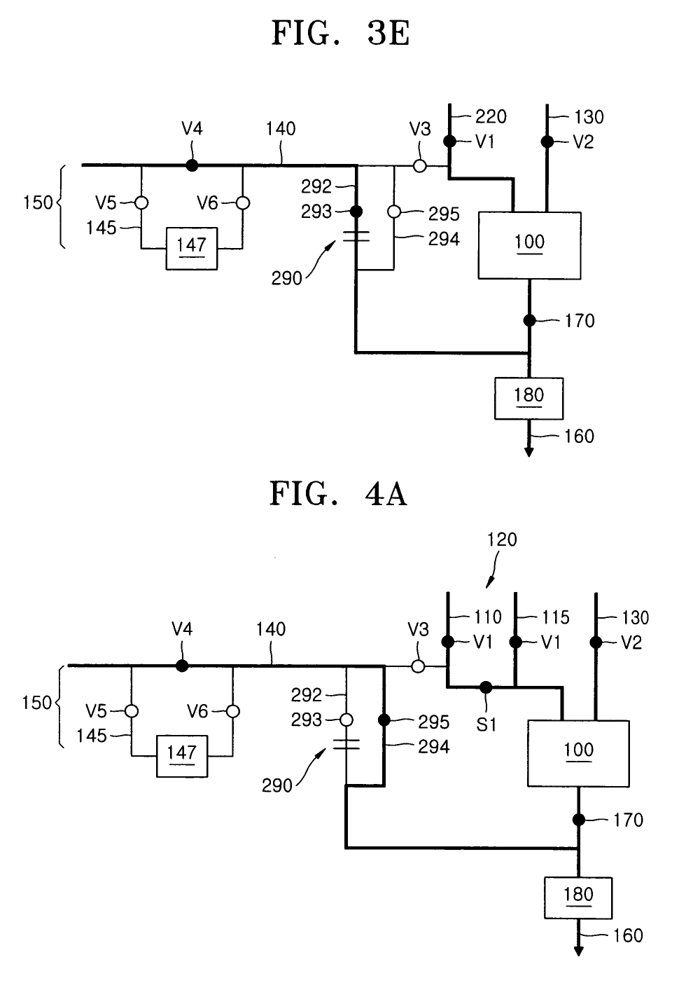

FIG. 3A is a schematic view of an ALD apparatus in a stand-by mode according to another embodiment of the present invention, and FIGS. 3B through 3E are schematic views illustrating respective process steps of an ALD method that are performed using the ALD apparatus illustrated in FIG. 3A. FIG. 3B illustrates supply of a source gas, FIG. 3C illustrates supply of a source purge gas, FIG. 3D illustrates supply of a reactant gas, and FIG. 3E illustrates supply of a reactant purge gas. In the figures, a black circle refers to an open valve, a white circle refers to a closed valve, and a line through which a gas is flowing is illustrated with a darkened, solid line. FIG. 3A illustrates a basic structure of the ALD apparatus, and FIGS. 3B through 3D each illustrate an operating state of the ALD apparatus depending on whether a valve is opened or closed off and whether or not a reactant gas is supplied.

Referring to FIG. 3A, a main purge line 220 and a reactant gas line 130 are connected to a reactor 100 where reactions occur. A first valve v1 is installed in the main purge line 220, and a second valve v2 is installed in the reactant gas line 130.

A source gas line 150 is connected to the main purge line 220 by a third valve v3. The source gas line 150 includes a source purge line 140 having a fourth valve v4 and a source gas supply line 145 having both terminals connected to the source purge line 140. The source gas supply line 145 passes through a source bottle 147 and has a front terminal and a rear terminal at which a fifth valve v5 and a sixth valve v6 are installed, respectively. Any non-reacted source gas, reactant gas, and purge gas, which remain in the reactor 100 after reactions, are exhausted through the exhaust line 160, to which a throttle valve 170 and a pump 180 are connected.

A vent line 290 is branched from the source gas line 150 and connected to the exhaust line 160 between the throttle valve 170 and the pump 180. Noticeably, the vent line 290 of the present embodiment includes a first vent line 292, a second vent line 294 having a higher conductance than the first vent line 292, and valves 293 and 295 installed in the first and second vent lines 292 and 294, respectively. The ALD apparatus of the second embodiment is characterized by the vent line 290 comprised of a dual vent line, i.e., the first and second vent lines 292 and 294. For example, the second vent line 294 has an inside diameter of 4 mm, and the first vent line 292 has an inside diameter of 1 mm.

When the ALD apparatus is in a stand-by mode as illustrated in FIG. 3A, the third, fifth, and sixth valves v3, v5, and v6 and the valve 293 of the first vent line 292 are closed off, and the first, second, and fourth valves v1, v2, and v4 and the valve 295 of the second vent line 294 are opened. As a result, the ALD apparatus is in the same operating state as the stand-by ALD apparatus of the first embodiment.

An example of an ALD method using the ALD apparatus illustrated in FIGS. 3A through 3E is as follows. At the outset, a wafer is mounted in the reactor 100, and the ALD apparatus is in a stand-by mode as illustrated in FIG. 3A. Then, a process including steps illustrated in FIGS. 3B through 3E is referred to a cycle, and the process is repeated for a number of cycles until a layer having a desired thickness is deposited on the wafer.

FIG. 3B illustrates supply of the source gas using the ALD apparatus illustrated in FIG. 3A. The fourth valve v4 and the valves 293 and 295 of the first and second vent lines 292 and 294 are closed off and the remaining valves v1, v2, v3, v5, and v6 are opened, so that the source gas is supplied to the reactor 100. As a result, the ALD apparatus is in the same operating state as the ALD apparatus of the first embodiment, in which the source gas is being supplied.

FIG. 3C illustrates supply of the source purge gas using the ALD apparatus illustrated in FIG. 3A and illustrates the same operating state as in FIG. 3A. Specifically, the third, fifth, and sixth valves v3, v5, and v6 and the valve 293 of the first vent line 292 are closed off, while the first, second, and fourth valves v1, v2, and v4 and the valve 295 of the second vent line 294 are opened. By opening the valve 295 of the second vent line 294, the source purge gas is exhausted through the second vent line 294 having a relatively high conductance so that the source gas can be efficiently purged.

FIG. 3D illustrates supply of the reactant gas using the ALD apparatus illustrated In FIG. 3A. In this case, the reactant gas is supplied through the reactant gas line 130 to the reactor 100, the third, fifth, and sixth valves v3, v5, and v6 and the valve 295 of the second vent line 294 are closed off, and the first, second, and fourth valves v1, v2, and v4 and the valve 293 of the first vent line 292 are opened.

FIG. 3E illustrates supply of the reactant purge gas using the ALD apparatus illustrated in FIG. 3A. Although the opening/closing states of the valves are the same as in FIG. 3D, only the reactant purge gas is supplied through the reactant gas line 130.

As can be seen from FIGS. 3D and 3E, when the reactant gas is supplied or purged, the valve 293 of the first vent line 292 is opened and the valve 295 of the second vent line 294 is closed off so that the purge gas flows into only the first vent line 292 having a relatively low conductance. Thus, pressure applied to the entire vent line 290 increases. Subsequently, when the source gas is supplied as illustrated in FIG. 3B, initial pressure applied to the source bottle 147 increases. Accordingly, a large amount of source gas is supplied to the reactor 100 in a short time, so that the source gas supplied to the surface of the wafer is rapidly saturated. For example, a time taken to raise the pressure applied to the source bottle 147 from 17 to 31 Torr can be reduced to 0.05 second. In the present embodiment, the source gas, which is even more difficult to supply and purge than the reactant gas, can be efficiently supplied and purged.

Meanwhile, although a case where the third valve v3 is closed off is exemplarily described with reference to FIGS. 3D and 3E, if it is more efficient to remove a dead volume as described above with reference to FIG. 2D and 2E by opening the third valve v3 than to raise the pressure applied to the vent line 290 by closing off the third valve v3, the third valve v3 can be opened.

### Embodiment 3

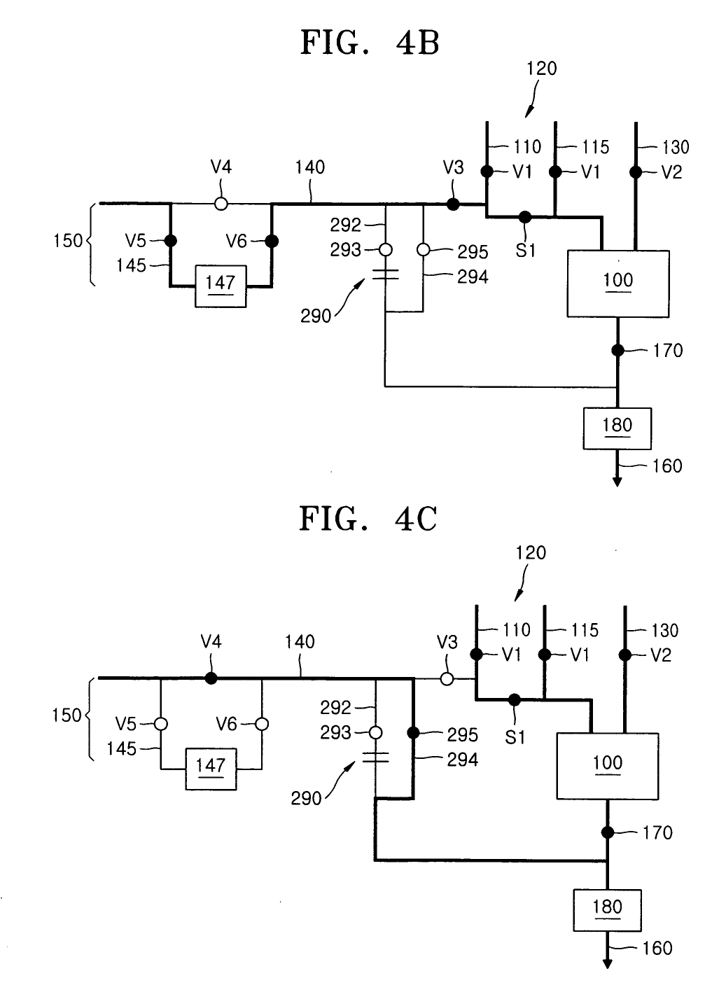

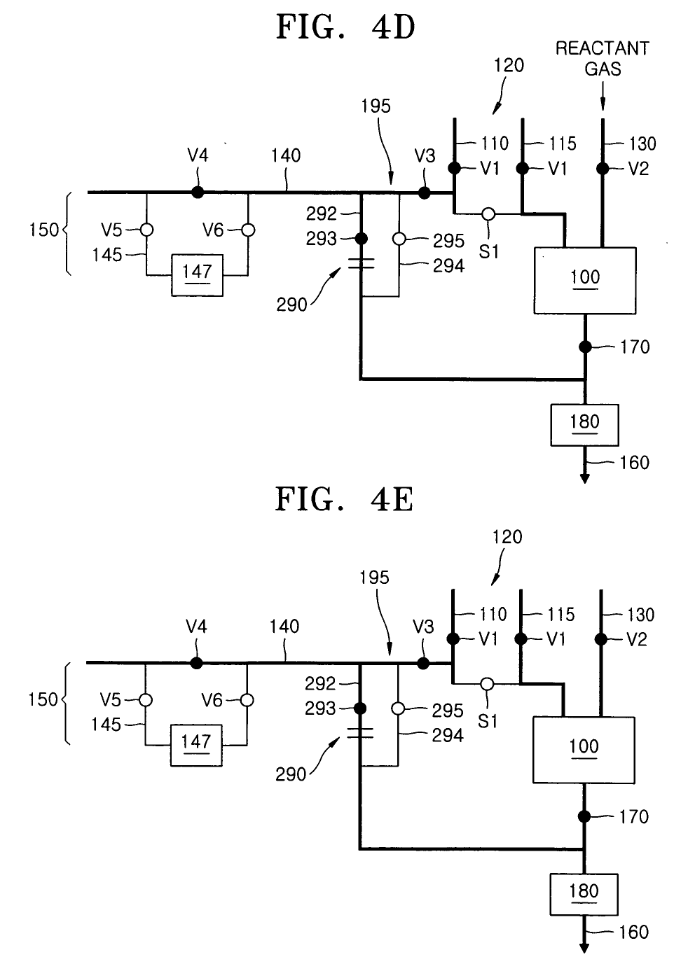

FIG. 4A is a schematic view of an ALD apparatus in a stand-by mode according to yet another embodiment of the present invention, and FIGS. 4B through 4E are schematic views illustrating respective process steps of an ALD method that are performed using the ALD apparatus illustrated in FIG. 4A. Specifically, FIG. 4B illustrates supply of a source gas, FIG. 4C illustrates supply of a source purge gas, FIG. 4D illustrates supply of a reactant gas, and FIG. 4E illustrates supply of a reactant purge gas. In the figures, a black circle refers to an open valve, a white circle refers to a closed valve, and a line through which a gas is flowing is illustrated with a darkened, solid line. FIG. 4A illustrates a basic structure of the ALD apparatus, and FIGS. 4B through 4D each illustrate an operating state of the ALD apparatus depending on whether a valve is opened or closed off and whether or not a reactant gas is supplied. It can be understood that the present embodiment is a combination of the first and second embodiments.

Referring to FIG. 4A, a main purge line 120 is connected to a reactor 100 where reactions occur. Like in the first embodiment, the main purge line 120 includes a first main purge line 110, a second main purge line 115, and a selection valve s1 installed at a connection portion between the first and second main purge lines 110 and 115. Each of the first and second main purge lines 110 and 115 has a first valve v1 installed at a terminal of the selection valve s1. The reactor 100 is connected to a reactant gas line 130, through which a reactant gas and a reactant purge gas are supplied to the reactor 100, and a second valve v2 is installed in the reactant gas line 130.

A source gas line 150, through which a source gas and a source purge gas are supplied to the reactor 100, is connected to the main purge line 120 by a third valve v3. The source gas line 150 includes a source purge line 140 having a fourth valve v4 and a source gas supply line 145 having both terminals connected to the source purge line 140. The source gas supply line 145 passes through a source bottle 147 and has a front terminal and a rear terminal at which a fifth valve v5 and a sixth valve v6 are installed, respectively. A non-reacted source gas, reactant gas, and purge gas, which remain in the reactor 100 after reactions, are exhausted through an exhaust line 160, to which a throttle valve 170 and a pump 180 are connected.

A vent line 290 is branched from the source gas line 150 and connected to the exhaust line 160 between the throttle valve 170 and the pump 180. Like in the second embodiment, the vent line 290 includes a first vent line 292, a second vent line 294 having a higher conductance than the first vent line 292, and valves 293 and 295 installed in the first and second vent lines 292 and 294, respectively.

As can be seen from FIG. 4A, when the ALD apparatus is in a stand-by mode, the third, fifth, and sixth valves v3, v5, and v6 and the valve 293 of the first vent line 292 are closed off, and the first, second, and fourth valves v1, v2, and v4 and the valve 295 of the second vent line 294 are opened. In particular, the selection valve s1 is opened such that the entire purge gas supplied to the first and second main purge lines 110 and 115 flows into the reactor 100. For example, a purge gas of 50 sccm is supplied to each of the first and second main purge lines 110 and 115, thus allowing a purge gas of 100 sccm to flow into the reactor 100.

An example of an ALD method using the ALD apparatus illustrated in FIGS. 4A through 4E is as follows. At the outset, a wafer is mounted in the reactor 100, and the ALD apparatus is in a stand-by mode as illustrated in FIG. 4A. Then, a process including steps illustrated in FIGS. 4B through 4E is referred to a cycle, and the process is repeated for a number of cycles until a layer having a desired thickness is deposited on the wafer.

FIG. 4B illustrates supply of the source gas using the ALD apparatus illustrated In FIG. 4A. The fourth valve v4 and the valves 293 and 295 of the first and second vent lines 292 and 294 are closed off and the remaining valves v1, v2, v3, v5, and v6 are opened such that the source gas is supplied to the reactor 100. The selection valve s1 is also opened such that both the first and second main purge lines 110 and 115 communicate with the reactor 100, thus allowing the entire purge gas to flow into the reactor 100.

FIG. 4C illustrates supply of the source purge gas using the ALD apparatus illustrated in FIG. 4A and illustrates the same operating state as in FIG. 4A. That is, the third, fifth, and sixth valves v3, v5, and v6 and the valve 293 of the first vent line 292 are closed off, while the first, second, and fourth valves v1, v2, and v4 and the valve 295 of the second vent line 294 are opened. The selection valve s1 is also opened such that the entire purge gas supplied to the first and second main purge lines 110 and 115 flows into the reactor 100. By opening the valve 295 of the second vent line 294, the source purge gas is exhausted through the second vent line 294 having a relatively high conductance so that the source gas can be efficiently purged.

FIG. 4D illustrates supply of the reactant gas using the ALD apparatus illustrated in. FIG. 4A. The reactant gas is supplied through the reactant gas line 130 to the reactor 100, the fifth and sixth valves v5 and v6, the valve 295 of the second vent line 294, and the selection valve s1 are closed off, and the first through fourth valves v1, v2, v3, and v4 and the valve 293 of the first vent line 292 are opened. Then, only the second main purge line 115 communicates with the reactor 100 so that some of the purge gas supplied to the first main purge line 110 flows toward the vent line 290, while the other of the purge gas supplied to the second main purge line 115 flows toward the reactor 100. For example, if a purge gas of 50 sccm is supplied to each of the first and second main purge lines 110 and 115, as the selection valve s1 is closed off, only the purge gas of 50 sccm flowing from the second main purge line 115 is supplied to the reactor 100. By closing off the selection valve s1, the amount of purge gas supplied to the reactor 100 is reduced so that the partial pressure of the reactant gas can increase. Also, the purge gas supplied to the first main purge line 110 flows toward the vent line 190, so that even a portion 195 corresponding to a dead volume of a conventional ALD apparatus can be purged.

FIG. 4E illustrates supply of the reactant purge gas using the ALD apparatus illustrated in FIG. 4A and illustrates the same operating state as in FIG. 4D, but only the purge gas is supplied to the reactant gas line 130. Similarly, the portion 195 corresponding to the dead volume of the conventional ALD apparatus is purged due to the purge gas flowing through the first main purge line 110.

As can be seen from FIGS. 4D and 4E, when the reactant gas is supplied or purged, the valve 293 of the first vent line 292 is opened and the valve 295 of the second vent line 294 is closed off so that the purge gas flows into only the first vent line 292 having a relatively low conductance. Thus, pressure applied to the entire vent line 290 increases. Subsequently, when the source gas is supplied as illustrated in FIG. 4B, initial pressure applied to the source bottle 147 increases. Accordingly, a large amount of source gas is supplied to the reactor 100 in a short time, so that the source gas supplied to the surface of the wafer is rapidly saturated. In the present embodiment, the source gas can be efficiently supplied and purged.

As described above, in the ALD apparatus and method of the present invention, the main purge line and/or the vent line each are comprised of a dual line. Thus, a selected line is appropriately changed during the supply of each of a source gas, a source purge gas, a reactant gas, and a reactant purge gas so that the source gas can be efficiently supplied and purged. Also, the dead volume that was generated in conventional embodiments, where the source gas was not purged and remained, can now be removed by the apparatus and method of the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An atomic layer deposition apparatus comprising:
a reactor where reactions occur;
a main purge line connected to the reactor and including a first main purge line, a second main purge line, and a selection valve installed at a connection portion between the first and second main purge lines;
a reactant gas line through which a reactant gas and a reactant purge gas are supplied to the reactor;
a source gas line through which a source gas and a source purge gas are supplied to the reactor;
an exhaust line through which any non-reacted source gas, reactant gas, and purge gas, which remain in the reactor after reactions, are exhausted; and
a vent line branched from the source gas line and connected to the exhaust line.

2. The apparatus of claim 1, wherein the selection valve is opened during supply of the source gas and during supply of the source purge gas.

3. The apparatus of claim 1, wherein the selection valve is closed off during supply of the reactant gas and during supply of the reactant purge gas.

4. The apparatus of claim 1, wherein each of the first and second main purge lines has a first valve,
a second valve is installed in the reactant gas line,
the source gas line is connected to the main purge line by a third valve,
the source gas line includes a source purge line having a fourth valve and a source gas supply line having both terminals connected to the source purge line,
the source gas supply line passes through a source bottle and has a front terminal and a rear terminal at which a fifth valve and a sixth valve are installed, respectively,
a throttle valve and a pump are connected to the exhaust line,
and the vent line branched from the source gas line has a seventh valve and is connected to the exhaust line between the throttle valve and the pump.

5. The apparatus of claim 4, wherein the fourth and seventh valves are closed off and the first, second, third, fifth, and sixth valves and the selection valve are opened during supply of the source gas.

6. The apparatus of claim 4, wherein the third, fifth, and sixth valves are closed off and the first, second, fourth, and seventh valves and the selection valve are opened during supply of the source purge gas.

7. The apparatus of claim 4, wherein the fifth and sixth valves and the selection valve are closed off and the first through fourth and seventh valves are opened during supply of the reactant gas and during supply of the reactant purge gas.

8. The apparatus of claim 1, wherein the vent line includes a first vent line, a second vent line having a higher conductance than the first vent line, and valves installed in the first and second vent lines, respectively.

9. The apparatus of claim 8, wherein the valve installed in the first vent line is closed off and the valve installed in the second vent line is opened during supply of the source purge gas.

10. The apparatus of claim 8, wherein the valve installed in the second vent line is closed off and the valve installed in the first vent line is opened during supply of the reactant gas and during supply of the reactant purge gas.

11. The apparatus of claim 8, wherein each of the first and second main purge lines has a first valve,
a second valve is installed in the reactant gas line,
the source gas line is connected to the main purge line by a third valve,
the source gas line includes a source purge line having a fourth valve and a source gas supply line having both terminals connected to the source purge line,
the source gas supply line passes through a source bottle and has a front terminal and a rear terminal at which a fifth valve and a sixth valve are installed, respectively,
a throttle valve and a pump are connected to the exhaust line,
and the vent line branched from the source gas line has a seventh valve and is connected to the exhaust line between the throttle valve and the pump.

12. The apparatus of claim 11, wherein the fourth valve and the valves of the first and second vent lines are closed off and the first, second, third, fifth, and sixth valves and the selection valve are opened during supply of the source gas.

13. The apparatus of claim 11, wherein the third, fifth, and sixth valves and the valve of the first vent line are closed off and the first, second, and fourth valves, the selection valve, and the valve of the second vent line are opened during supply of the source purge gas.

14. The apparatus of claim 11, wherein the fifth and sixth valves, the selection valve, and the valve of the second vent line are closed off and the first through fourth valves and the valve of the first vent line are opened during supply of the reactant gas and during supply of the reactant purge gas.

15. The apparatus of claim 1, wherein the main purge line is connected to the source gas line by a valve.

16. An atomic layer deposition apparatus comprising:
a reactor where reactions occur;
a main purge line connected to the reactor;
a reactant gas line through which a reactant gas and a reactant purge gas are supplied to the reactor;
a source gas line through which a source gas and a source purge gas are supplied to the reactor;
an exhaust line through which any non-reacted source gas, reactant gas, and purge gas, which remain in the reactor after reactions, are exhausted; and
a vent line branched from the source gas line and connected to the exhaust line, the vent line including a first vent line, a second vent line having a higher conductance than the first vent line, and valves installed in the first and second vent lines, respectively.

17. The apparatus of claim 16, wherein the valve of the first vent line is closed off and the valve of the second vent line is opened during supply of the source purge gas.

18. The apparatus of claim 16, wherein the valve of the second vent line is closed off and the valve of the first vent line is opened during supply of the reactant gas and during supply of the reactant purge gas.

19. The apparatus of claim 16, wherein a first valve is installed in the main purge line,
a second valve is installed in the reactant gas line,
a third valve is installed in the main purge line,
the source gas line includes a source purge line having a fourth valve and a source gas supply line having both terminals connected to the source purge line,
the source gas supply line passes through a source bottle and has a front terminal and a rear terminal at which a fifth valve and a sixth valve are installed, respectively,
a throttle valve and a pump are connected to the exhaust line, and
the vent line branched from the source gas line is connected to the exhaust line between the throttle valve and the pump.

20. The apparatus of claim 19, wherein the fourth valve and the valves of the first and second vent lines are closed off and the first, second, third, fifth, and sixth valves are opened during supply of the source gas.

21. The apparatus of claim 19, wherein the third, fifth, and sixth valves and the valve of the first vent line are closed off and the first, second, and fourth valves and the valve of the second vent line are opened during supply of the source purge gas.

22. The apparatus of claim 19, wherein the fifth and sixth valves and the valve of the second vent line are closed off and the first, second, and fourth valves and the valve of the first vent line are opened during supply of the reactant gas and during supply of the reactant purge gas.

23. An atomic layer deposition method using an atomic layer deposition apparatus that includes a reactor and a main purge line connected to the reactor and having a first main purge line, a second main purge line, and a selection valve installed at a connection portion between the first and second main purge lines, the method comprising:
mounting a wafer in a reactor where reactions occur;
supplying a source gas to the reactor by opening the selection valve such that both the first and second main purge lines communicate with the reactor;
supplying a source purge gas to the reactor by opening the selection valve such that both the first and second main purge lines communicate with the reactor;
supplying a reactant gas to the reactor by closing off the selection valve such that only the second main purge line communicates with the reactor; and
supplying a reactant purge gas to the reactor by closing off the selection valve such that only the second main purge line communicates with the reactor.

24. The method of claim 23, wherein a vent line is connected between a source gas line, through which the source gas and the source purge gas are supplied to the reactor, and an exhaust line, through which a non-reacted source gas, reactant gas, and purge gas remaining in the reactor after reactions are exhausted, and wherein the vent line includes a first vent line, a second vent line having a higher conductance than the first vent line, and valves installed in the first and second vent lines, respectively.

25. The method of claim 24, wherein the supplying of the source purge gas comprises closing off the valve of the first vent line and opening of the valve of the second vent line.

26. The method of claim 24, wherein the supplying of the reactant gas and the supplying of the reactant purge gas comprise closing off the valve of the second vent line and opening the valve of the first vent line.

27. An atomic layer deposition method using an atomic layer deposition apparatus that includes a vent line connected between a source gas line, through which a source gas and a source purge gas are supplied to the reactor, and an exhaust line, through which a non-reacted source gas, reactant gas, and purge gas remaining in the reactor after reactions are exhausted, the vent line having a first vent line, a second vent line having a higher conductance than the first vent line, and valves installed in the first and second vent lines, respectively, the method comprising:
mounting a wafer in a reactor where reactions occur;
supplying the source gas to the reactor by closing off the valves of the first and second vent lines;
supplying the source purge gas to the reactor by closing off the valve of the first vent line and opening the valve of the second vent line;
supplying a reactant gas to the reactor by closing off the valve of the second vent line and opening the valve of the first vent line; and
supplying a reactant purge gas to the reactor by closing off the valve of the second vent line and opening the valve of the first vent line.
